(19) United States
(12) Patent Application Publication
(10) Pub. No.: US 2017/0250654 A1
(43) Pub. Date: Aug. 31, 2017

(54) DYNAMIC DEAD TIME MANAGEMENT

(71) Applicant: QUALCOMM Incorporated, San Diego, CA (US)

(72) Inventor: William COPE, Maricopa, AZ (US)

(21) Appl. No.: 15/443,503

(22) Filed: Feb. 27, 2017

Related U.S. Application Data
(60) Provisional application No. 62/301,467, filed on Feb. 29, 2016.
(60) Provisional application No. 62/301,513, filed on Feb. 29, 2016.

(51) Int. Cl. H03F 1/02; H03F 3/217; H03F 3/185

(52) U.S. Cl. CPC H03F 1/0233; H03F 3/185; H03F 3/2171; H03F 2200/03; H03F 2200/102; H03F 2200/78; H03F 2200/391; H03F 2200/351

(57) ABSTRACT

Certain aspects of the present disclosure provide methods and apparatus for dynamically managing the dead time between turning on output power stage transistors in amplifiers, such as audio amplifiers. One example method of operating an amplifier generally includes generating a drive signal based on an input signal; amplifying the drive signal by alternatively driving a first transistor and a second transistor with a time between deactivating the first transistor and activating the second transistor; and adjusting the time based on a parameter of the input signal or the drive signal, during the amplifying. For example, the parameter may include an amplitude of the input signal, a duty cycle of the drive signal, or a duty cycle of a modulated signal (e.g., a pulse-width modulated signal) generated based on the input signal. The input signal may be a digital audio input signal.

### CLAIM OF PRIORITY UNDER 35 U.S.C. §119

The present application claims the benefit of U.S. Provisional Application Ser. No. 62/301,467, entitled “DYNAMIC DEAD TIME MANAGEMENT” and filed Feb. 29, 2016, and U.S. Provisional Application Ser. No. 62/301,513, entitled “PERFORMANCE PROTECTION OF AUDIO POWER AMPLIFIER (PA) DURING HIGH MODULATION” and filed Feb. 29, 2016, both of which are assigned to the assignee of the present application and are expressly incorporated by reference herein in their entirety.

### TECHNICAL FIELD

Certain aspects of the present disclosure generally relate to electronic circuits and, more particularly, to managing dead time in amplifiers.

### BACKGROUND

Various electronic systems are capable of processing digital audio signals and amplifying the processed signals to drive a speaker, thereby producing sound waves. Examples of such systems include portable media player devices, cellular telephones, smartphones, tablets, computers, radios, audio recorders, stereo equipment (e.g., audio receivers), components in a vehicle, and the like. For digital audio processing, an encoder-decoder (CODEC) may be used to convert analog audio signals to encoded digital signals and vice versa. For example, a CODEC may receive an analog audio signal (e.g., from a microphone), and convert the analog audio signal into a digital signal that can be processed (e.g., digitally filtered) via a digital signal processor (DSP). The CODEC can then convert the processed digital output of the DSP to an analog signal for use by audio speakers, for example, via a digital-to-analog converter (DAC).

Amplification of digital or analog audio signals may be performed using any of various suitable techniques. Class-D amplifiers are widely used in audio applications because these types of amplifiers may be more efficient than class-AB amplifiers and involve less heat management and external components (e.g., heatsinks). A class-D amplifier generally refers to an electronic amplifier in which the transistors in the output stage operate as electronic switches, instead of as linear gain devices, as in other amplifier types. In a class-D amplifier, the signal to be amplified is a train of pulses of constant amplitude, but varying width and separation (e.g., different duty cycle), so the output stage transistors switch rapidly back and forth between fully conductive and nonconductive states. Before being applied to the amplifier, the signal to be amplified is converted to a pulse train using pulse width modulation, pulse density modulation, or other suitable techniques. The amplified pulse train output by the transistors can be converted back to an analog audio signal by low-pass filtering the pulse train to remove the unwanted high-frequency components introduced by pulse modulation and recover the desired low-frequency signal.

Despite their benefits, class-D amplifiers may have some drawbacks, such as lower linearity and/or lower power supply rejection ratio (PSRR) in certain aspects when compared to other amplifier implementations. In order to improve the overall performance of class-D amplifiers, feedback can be applied around the output power stage. This feedback may increase the linearity of the class-D output stage and may attenuate power supply ripple present in the audio band (e.g., intermodulation products between the main signal and the power supply tones).

### SUMMARY

Certain aspects of the present disclosure generally relate to dynamically managing the time between turning on output power stage transistors in amplifiers (e.g., “dead time”).

Certain aspects of the present disclosure provide a method of operating an amplifier. The method generally includes generating a drive signal based on an input signal; amplifying the drive signal by alternatively driving a first transistor and a second transistor with a time between deactivating the first transistor and activating the second transistor; and adjusting the time based on a parameter of the input signal or the drive signal, during the amplifying.

Certain aspects of the present disclosure provide an amplifier. The amplifier generally includes circuitry configured to generate a drive signal based on an input signal; first and second transistors configured to generate an amplified signal; and first and second drivers coupled to the first and second transistors, respectively, and configured, based on the drive signal, to alternatively drive the first transistor and the second transistor with a time between deactivating the first transistor and activating the second transistor, wherein the time varies based at least in part on a parameter of the input signal or the drive signal.

Certain aspects of the present disclosure provide an apparatus for amplifying an input signal. The apparatus generally includes means for generating a drive signal based on the input signal; means for amplifying the drive signal by alternatively driving first and second means for switching with a time between deactivating the first means for switching and activating the second means for switching; and means for adjusting the time based on a parameter of the input signal or the drive signal, during the amplifying.

Certain aspects of the present disclosure provide a method of operating an amplifier. The method generally includes amplifying a signal by alternatively driving a first transistor and a second transistor with a time between deactivating the first transistor and activating the second transistor and adjusting the time based on a parameter of the amplified signal, during the amplifying.

Certain aspects of the present disclosure provide an amplifier. The amplifier generally includes first and second transistors configured to generate an amplified signal; and first and second drivers coupled to the first and second transistors, respectively, and configured to alternatively drive the first transistor and the second transistor with a time between deactivating the first transistor and activating the second transistor, wherein the time varies based at least in part on a parameter of the amplified signal. For certain aspects, the parameter is a duty cycle or an amplitude of the amplified signal.

Certain aspects of the present disclosure provide an apparatus for amplifying a signal. The apparatus generally includes means for amplifying the signal by alternatively driving first and second means for switching with a time between deactivating the first means for switching and activating the second means for switching; and means for adjusting the time based on a parameter of the amplified signal, during the amplifying.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1A is a block diagram of an example class-D amplifier with feedback in a single-ended (SE) configuration, in accordance with certain aspects of the present disclosure.

FIG. 1B is a block diagram of an example class-D amplifier with feedback in a bridge-tied load (BTL) configuration, in accordance with certain aspects of the present disclosure.

FIG. 2 is a block diagram of an example direct digital feedback amplifier (DDFA) for a BTL configuration, in accordance with certain aspects of the present disclosure.

FIG. 3 is an example graph illustrating dynamically changing a dead time for output stage transistors in an amplifier based on a signal level, in accordance with certain aspects of the present disclosure.

FIG. 4 illustrates timing diagrams of example gate-drive signals for the output stage transistors in an amplifier, where the gate-drive signals have different dead times, in accordance with certain aspects of the present disclosure.

FIG. 5 is an example graph illustrating dynamically changing a dead time for output stage transistors in an amplifier based on a signal level, in accordance with certain aspects of the present disclosure.

FIGS. 6A to 6C illustrate different methods for detecting a signal level to dynamically adjust the dead time for the output stage transistors in an amplifier, in accordance with certain aspects of the present disclosure.

FIGS. 7 and 8 are flow diagrams of example operations for operating an amplifier, in accordance with certain aspects of the present disclosure.

### DETAILED DESCRIPTION

Certain aspects of the present disclosure provide techniques and apparatus for dynamically managing the dead time between turning on output power stage transistors in amplifiers, such as amplifiers for audio applications.

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Class-D Amplifiers

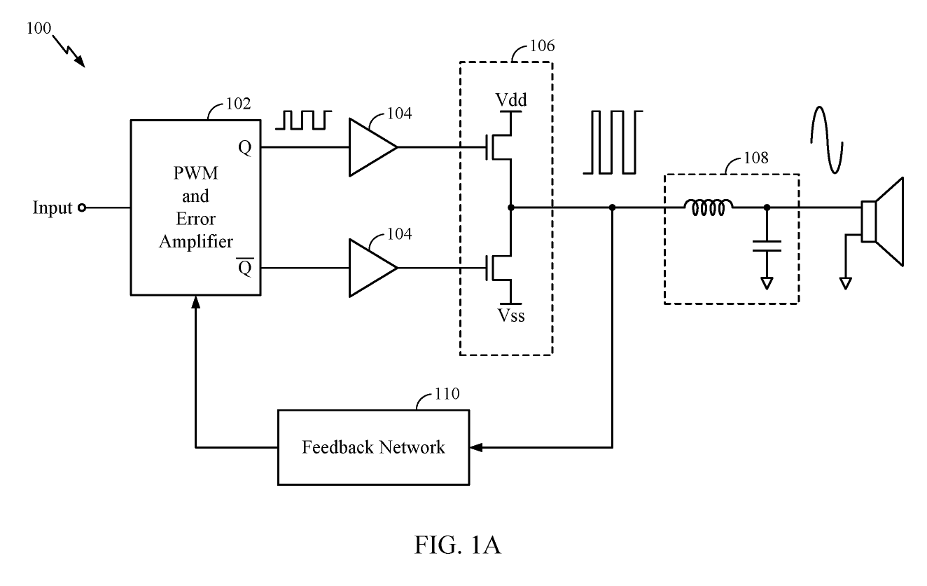

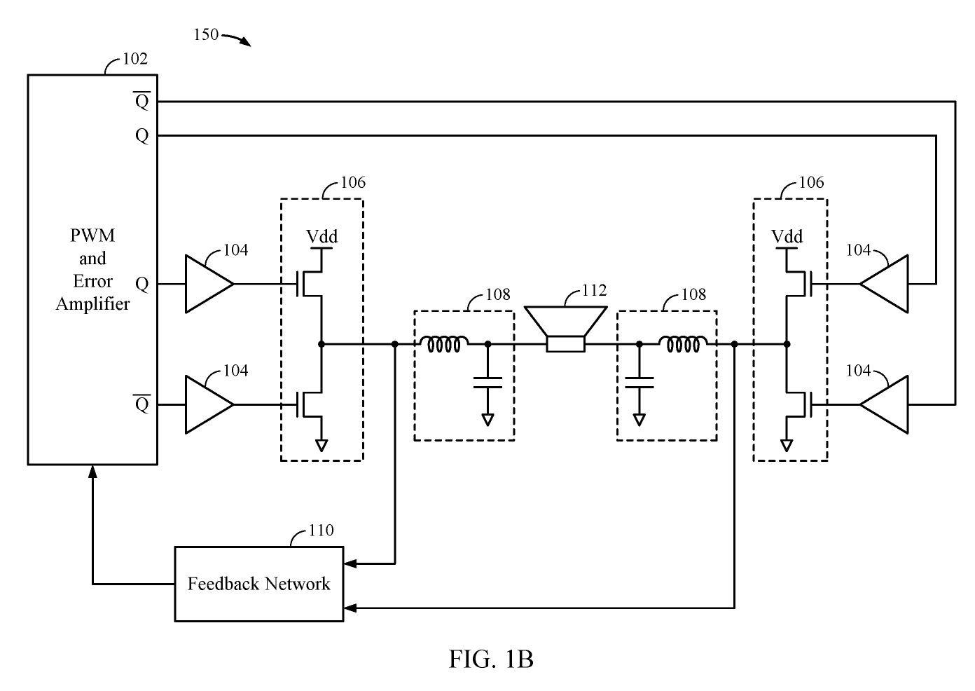

FIG. 1A is a block diagram of an example class-D amplifier 100 in a single-ended (SE) configuration (also known as a half-bridge topology), in accordance with certain aspects of the present disclosure. The class-D amplifier 100 may include a pulse width modulator (PWM) and error amplifier stage 102, drivers 104, an output stage 106, a low-pass filter (LPF) 108, and a feedback network 110. The output of the class-D amplifier 100 may be used to drive a load (e.g., a speaker 112, as illustrated). The input signal to be amplified may be encoded into a train of square pulses of constant amplitude using pulse width modulation in the PWM and error amplifier stage 102. For certain aspects, the pulse train may be generated by comparing the input signal with a high frequency triangle waveform, where the triangle waveform defines both the input amplitude for full modulation and the switching frequency. The PWM and error amplifier stage 102 outputs the pulse train signal (on Q) and its inverse (on Q_bar) to the drivers 104.

The drivers 104 are configured to produce high current signals to charge and discharge the output stage capacitance (e.g., the gate capacitance if the output stage comprises field-effect transistors (FETs)) during the switching interval to ensure fast rise/fall times of the transistors in the output stage 106. The drivers 104 may be implemented with any of various suitable topologies, such as using inverter/level shifters. The transistors in the output stage 106 may be configured with a push-pull topology, as illustrated. The output stage 106 may include FETs, which may include, for example: (1) two n-channel metal-oxide semiconductor (NMOS) transistors or (2) one p-channel metal-oxide semiconductor (PMOS) transistor and one NMOS. In an SE configuration, the high-side transistor may be connected to a positive supply voltage (Vdd), and the low-side transistor may be connected to a negative supply voltage (Vss), as shown.

With the alternate switching of the transistors between the power supply voltages, as controlled by the drivers based on the pulse train signal (Q) and its inverse (Q_bar), the output signal from the output stage 106 is an amplified version of the pulse train. The LPF 108 filters the signal output by the output stage 106 to remove the high-frequency components introduced by the modulation and recover the desired signal. For certain aspects, the LPF 108 may be implemented with a series inductor and a shunt capacitor, as illustrated. The filtered signal output from the LPF 108 may be used to drive the load (e.g., the speaker 112 in the case of audio amplifiers).

The introduction of dead time between deactivation of the high-side transistor and activation of the low-side transistor (or vice versa)—for example, to prevent shoot-through current between the power supply rails if both transistors were on concurrently—may lead to nonlinear output impedance. Furthermore, the LPF 108 has a highly load-dependent frequency response in many implementations. These sources of errors may be mitigated in some implementations with negative feedback, which is implemented with the feedback network 110 connected between the output of the output stage 106 and an error amplifier in the PWM and error amplifier stage 102. The feedback network 110 may include a voltage divider and one or more integrators, for example, to effectively back out the effects of amplification and modulation and produce an error-inclusive signal that can be compared to the desired (audio) input signal.

FIG. 1B is a block diagram of an example class-D amplifier 150 in a bridge-tied load (BTL) configuration (also known as a full-bridge topology), in accordance with certain aspects of the present disclosure. The BTL configuration includes two output stages 106 whose outputs are filtered by two LPFs 108, and the filtered signals differentially drive the speaker 112. The transistors of the two output stages 106 are driven by four drivers 104, which are controlled by four output pulse trains from the PWM and error amplifier stage 102, as shown. The feedback network 110 may also receive inputs from the outputs of both output stages 106.

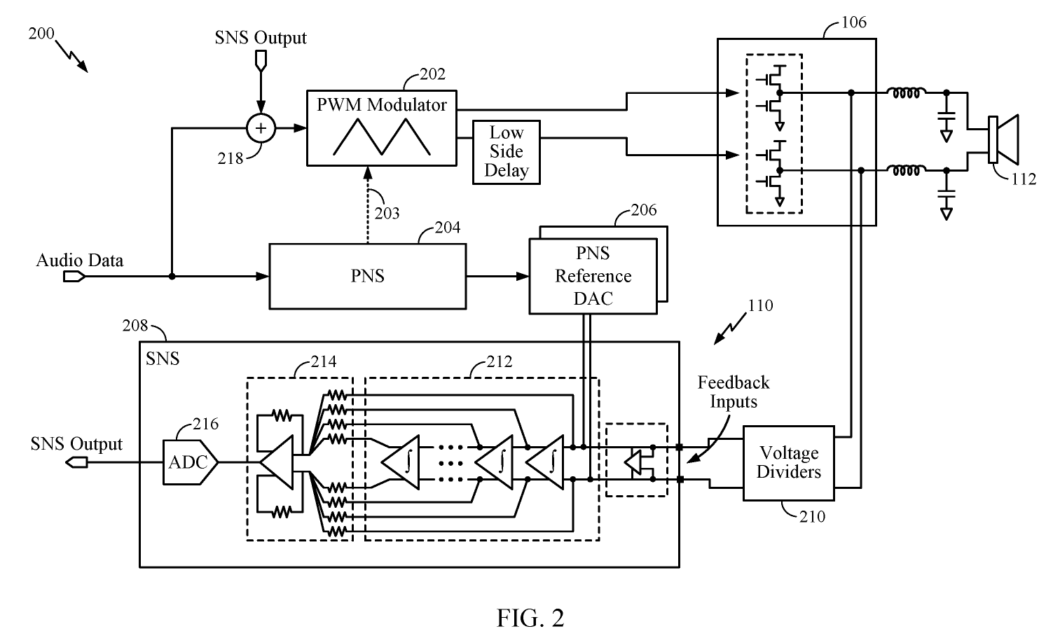

FIG. 2 is a block diagram of an example direct digital feedback amplifier (DDFA) 200, in accordance with certain aspects of the present disclosure. As used herein, a DDFA generally refers to an amplifier in which digital input signals can be directly modulated and used to drive an amplifier output stage, without first being converted to analog signals, and in which a feedback mechanism is used in an effort to correct for any amplification or modulation errors. Although the DDFA 200 in FIG. 2 is illustrated for a BTL configuration (similar to that described above for FIG. 1B), the DDFA may alternatively be configured for SE operation (similar to that described above for FIG. 1A).

The DDFA 200 may include a pulse width modulator 202, a primary noise shaper (PNS) 204, and a PNS reference digital-to-analog converter (DAC) 206. The PNS 204 may perform noise shaping, as part of the process of quantization, to increase the apparent signal-to-noise ratio (SNR) of the signal output to the PNS reference DAC 206. The feedback network 110 of the DDFA 200 may include a voltage divider stage 210 and a secondary noise shaper (SNS) 208, where the SNS 208 may include a series of integrators 212, a summation circuit 214, and an analog-to-digital converter (ADC) 216 (e.g., a flash ADC). The output of the SNS 208 may be combined with the digital audio input signal in a combiner 218 to implement the feedback mechanism, and the pulse width modulator 202 may encode the combined signal using pulse width modulation. The PNS 204 may include a series of digital integrators for digitally implementing delta-sigma modulation on the digital audio input signal before the modulated signal is converted to an analog signal by the PNS reference DAC 206. The PNS 204 may include a pulse width modulator to encode the delta-sigma modulated signal using pulse width modulation before conversion by the PNS reference DAC 206. The analog signal from the PNS reference DAC 206 is combined with the attenuated feedback signal from the voltage divider stage 210 in the SNS 208, and the SNS 208 performs analog delta-sigma modulation on the combined analog signal.

### Example Dynamic Dead Time Management

One component of efficiency loss in class-D amplifiers may be shoot-through current, which generally refers to current from one power supply, through both power amplifier transistors in the output stage 106, to the other power supply or ground during a period when both transistors are on. Dead time may be added to the amplifier circuits in an effort to mitigate this loss of efficiency or for other reasons. As used herein, “dead time” generally refers to the time between one transistor being turned off and the other transistor being turned on, or vice versa. The more dead time that is added, the more efficient the amplifier circuit may be (at least to a point). However, as dead time is added, the amount of energy that can be delivered to the load (e.g., the speaker 112) is reduced. Additionally, dead time may add distortion to the output signal. Accordingly, techniques and apparatus to effectively manage the dead time are presented herein.

Certain aspects of the present disclosure offer techniques and apparatus to dynamically change the dead time in an amplifier circuit to provide: (1) relatively larger dead time for low amplitude signals for high efficiency and (2) relatively lower dead time for high amplitude signals for high energy delivery and low distortion. Dead time control may be provided (e.g., by the PWM and error amplifier stage 102 or by the pulse width modulator 202) between the high-side and low-side power amplifier (PA) drivers 104. This effectively provides a high impedance between the supplies and the load during the dead time, which may reduce crow-bar current between the two supplies. The dead time may be varied between 0 ns and 20 ns, for example.

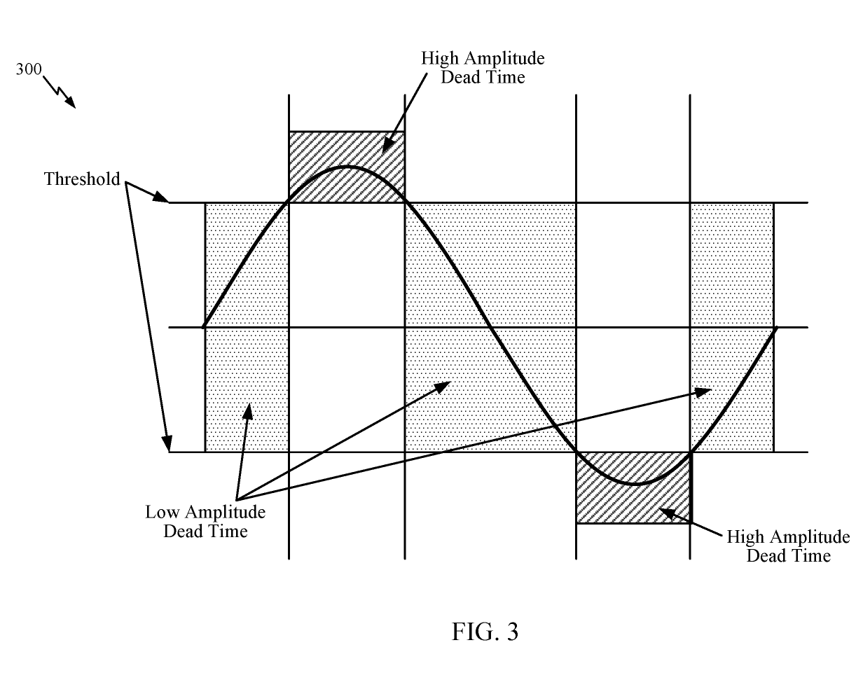

FIG. 3 is an example graph 300 illustrating dynamically changing a dead time for output stage transistors in an amplifier based on a signal level, in accordance with certain aspects of the present disclosure. When the signal level (e.g., of a digital audio input signal or an amplified analog audio signal) is lower, increased dead time may improve efficiency with no loss of output power. When the signal level is higher, reduced dead time may help increase the amount of power delivered to the load (e.g., the speaker 112). Therefore, the amplifier may have two regions of dead time controlled by a programmable threshold. When the signal level is below the threshold, the low-amplitude dead time value is applied. When the signal level is above the threshold, the high-amplitude dead time value is applied. The low-amplitude dead time value may be greater than the high-amplitude dead time value. For certain aspects, hysteresis may be utilized for adjusting the dead time values as the signal level transitions between the different threshold regions. The comparison between the signal level and the threshold may be performed by any suitable circuitry in or associated with the amplifier, such as a comparator in the PNS 204, the SNS 208, or in the PWM and error amplifier stage 102, as described in further detail below. The dead time may be adjusted by any suitable circuitry in or associated with the amplifier, such as by the pulse width modulator 202 or the PWM and error amplifier stage 102, as described in further detail below.

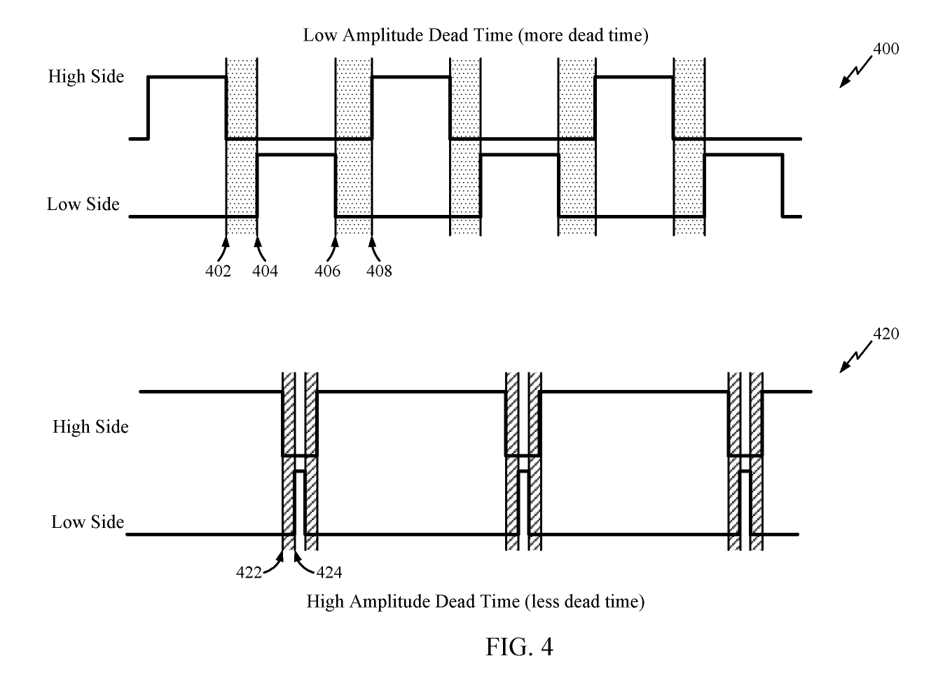

FIG. 4 illustrates timing diagrams 400, 420 of example gate-drive signals for the output stage transistors in an amplifier, where the gate-drive signals have different dead times in the different timing diagrams, in accordance with certain aspects of the present disclosure. For example, the gate-drive signals illustrated in FIG. 4 may be pulse-width modulated signals output by the drivers 104 in FIGS. 1A and 1B. The timing diagram 400 illustrates the low-amplitude dead time (relatively longer dead time) being used between deactivating the high-side transistor with the high-side gate driver at time 402 and activating the low-side transistor with the low-side gate driver at time 404 (or vice versa at times 406 and 408), when the signal of interest (e.g., the digital audio input signal or the amplified analog audio signal) has a relatively lower amplitude. The timing diagram 420 illustrates the high-amplitude dead time (relatively shorter dead time) being used between deactivating the high-side transistor with the high-side gate driver at time 422 and activating the low-side transistor with the low-side gate driver at time 424 (or vice versa), when the signal of interest has a relatively higher amplitude, as reflected by the longer pulse width (i.e., greater duty cycle) in the high-side gate-drive signal of timing diagram 420 compared to the high-side gate-drive signal of timing diagram 400. Although gate-drive signals are illustrated in FIG. 4, the timing diagrams 400, 420 may also be considered as representing the outputs of the PWM and error amplifier stage 102, the pulse width modulator 202, or the PNS reference DAC 206 (after encoding by the pulse width modulator in the PNS 204 and conversion to the analog domain by the DAC 206), which may be similar in appearance to the gate-drive signals, but may have lower amplitude.

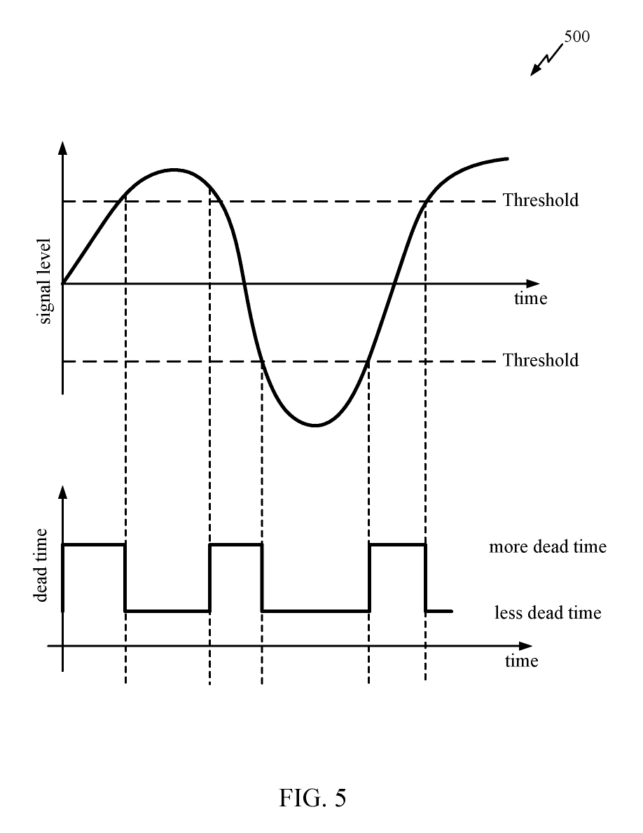

FIG. 5 is an example graph 500 illustrating dynamically changing a dead time for output stage transistors in an amplifier based on a signal level, in accordance with certain aspects of the present disclosure. The upper portion of the graph 500 illustrates the signal level relative to threshold values, while the lower portion of the graph indicates corresponding changes in the dead time for the output stage transistors. The signal level may be an amplitude of an input signal (e.g., a digital audio input signal) or of an amplified signal at the output of the amplifier. When the signal level is outside the threshold range (e.g., above the positive threshold if the signal level is positive, or below the negative threshold if the signal level is negative), a relatively shorter dead time is used (labeled “less dead time” in the lower portion of the graph 500). A relatively longer dead time (indicated as “more dead time” in the lower portion of the graph 500) is used if the signal is inside the threshold range (e.g., the absolute value of the signal level is below the threshold). For certain aspects, different threshold magnitudes may be used for the upper and lower thresholds.

According to certain aspects, there may be more than one threshold and more than two different dead times. For example, three different dead times may be used for the output stage transistors in an amplifier with two corresponding thresholds. In this case, the lowest dead time may be used when the absolute value of the signal level is greater than a relatively higher threshold, and the highest dead time may be used when the absolute value of the signal level is lower than a relatively lower threshold. An intermediate dead time (between the lowest and highest dead times) may be used when the absolute value of the signal level is between the lower and higher thresholds. For certain aspects, there may be some hysteresis in changing the dead times as the signal level transitions between the different threshold regions.

According to certain aspects, the dead time for the output stage transistors may be adjusted according to a function based on the signal level (e.g., of the input signal or feedback signal) or a duty cycle of the drive signal(s). For example, the dead time may be determined using a piecewise linear function or a continuous function, in which the dead time is inversely proportional to the signal level or duty cycle. This determination may be made through a calculation (e.g., using circuitry in or associated with the amplifier) or a comparison to a look up table (LUT) (e.g., stored in a memory), using a value representing the signal level or duty cycle.

Any of various suitable methods may be used to dynamically change the dead time in an amplifier circuit, which may be controlled by the PWM and error amplifier stage 102 or by the PNS 204 and pulse width modulator 202, for example. For certain aspects, in the case of the DDFA 200, the PNS 204 may detect a parameter of the input signal (or of a processed signal in the PNS 204 based on the input signal) and output a control signal via line 203 to the pulse width modulator 202, where the modulator effectively adjusts the dead time (e.g., by controlling the pulse widths of the signals output to the drivers 104). For other aspects, circuitry (e.g., a detector as described below) may detect a parameter of the analog output signal from the PNS reference DAC 206 (in the analog domain or in the digital domain after being converted to a digital signal using, for example, a comparator). The detector (which may be implemented as a standalone circuit or as part of the PNS 204, the SNS 208, or other circuitry) may output a control signal to the pulse width modulator 202 to effectively adjust the dead time. For other aspects, the SNS 208 may detect a parameter of the output signal (e.g., SNS Output from the ADC 216) (or of a preliminarily processed signal in the SNS 208 on which the output signal is based) and output a control signal to the pulse width modulator 202 to effectively adjust the dead time.

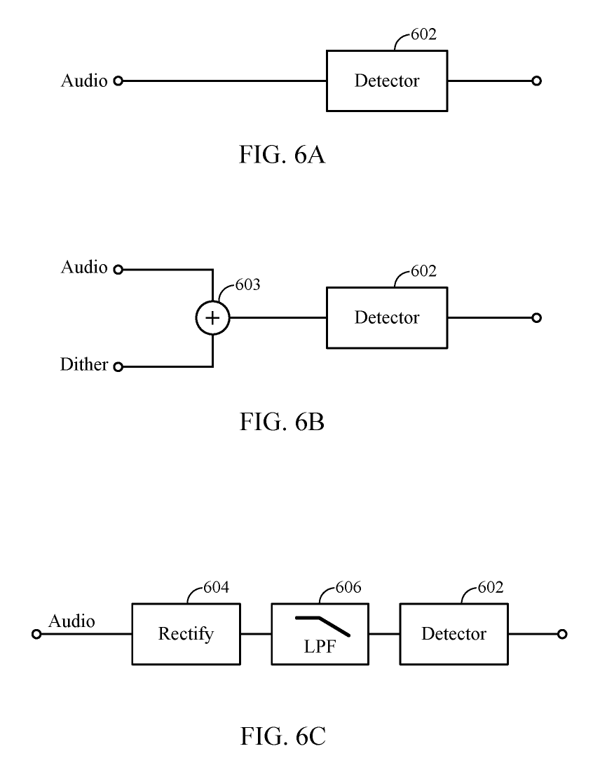

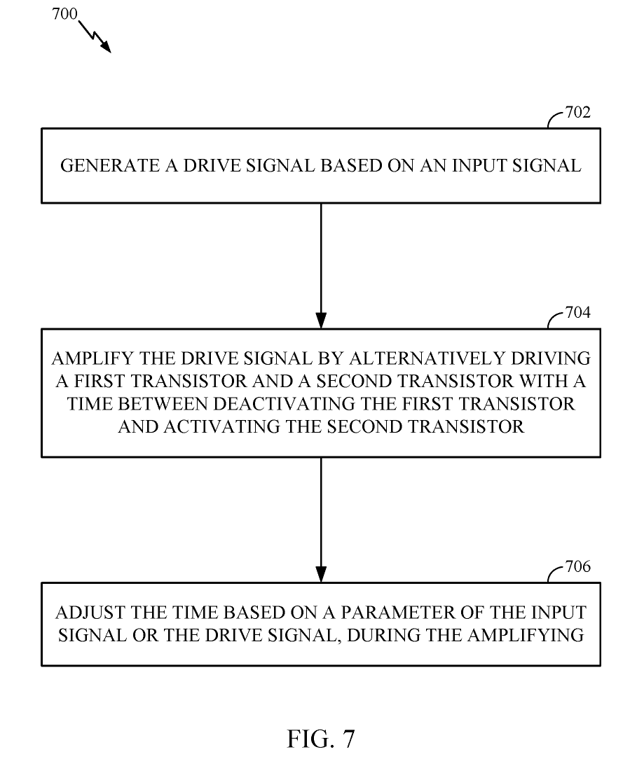

One example implementation may be based on a strict threshold as in FIG. 6A. In the strict-threshold method, when (an absolute value of) the signal level (e.g., of the input signal or of a signal based on the amplified signal) is below a programmable threshold (e.g., as determined by a detector 602), one dead time is used. When (an absolute value of) the signal level is above this threshold, another, different dead time is used. However, large differences between the different dead times when operating with the strict-threshold method may lead to increased distortion. For certain aspects, the detector 602 may be implemented in the PNS 204, the SNS 208, or in the PWM and error amplifier stage 102, which may receive a feedback signal from the feedback network 110 indicative of the signal level. The detector 602 may receive the (audio) input signal or the feedback signal to determine whether the signal level is above the threshold.

To help reduce the distortion added by using the strict-threshold method, dither may be applied (e.g., added) to the (audio) input signal or the feedback signal by a combiner 603 (e.g., a summer), before the signal level determination is made by the detector 602, as illustrated in FIG. 6B. For certain aspects, the combiner 603 may be implemented in the PNS 204, the SNS 208, or the PWM and error amplifier stage 102.

Another example method involves using an envelope-tracking mechanism. This envelope-tracking method may change the dead time on a slower time basis in an effort to prevent the dynamic dead time from creating distortion. For certain aspects, as depicted in FIG. 6C, the envelope-tracking method may involve: (1) rectifying the (audio) input signal or the feedback signal (e.g., with a rectifier 604, which may be analog or digital) to detect the envelope thereof; and (2) low-pass filtering (e.g., in a low-pass filter 606, which may be analog or digital) the detected envelope signal before the signal level determination is made by the detector 602. For certain aspects, the rectifier 604 and/or the low-pass filter 606 may be implemented in the PNS 204, the SNS 208, or the PWM and error amplifier stage 102.

FIG. 7 is a flow diagram of example operations 700 for operating an amplifier, in accordance with certain aspects of the present disclosure. The operations 700 may be performed, for example, by a circuit, such as the class-D amplifier 100 of FIG. 1A, the class-D amplifier 150 of FIG. 1B, or the DDFA of FIG. 2.

The operations 700 may begin, at block 702, with the circuit generating a drive signal based on an input signal. For certain aspects, the input signal is a digital signal (e.g., a digital audio signal). At block 704, the circuit may amplify the drive signal by alternatively driving a first transistor and a second transistor with a time between deactivating the first transistor and activating the second transistor (e.g., a dead time). At block 706, the circuit may adjust the time based on a parameter of the input signal or the drive signal, during the amplifying. The first transistor and the second transistor may both be deactivated during the dead time.

According to certain aspects, the amplifier is a class-D amplifier. In this case, generating the drive signal at block 702 may involve the circuit generating a pulse-width modulated drive signal based on the input signal (e.g., using the pulse width modulator 202 or the PWM and error amplifier stage 102).

According to certain aspects, the operations 700 may further include the circuit filtering the amplified signal. In this case, the amplified drive signal may include an amplified pulse-width modulated signal.

According to certain aspects, the parameter is an amplitude of the input signal. For certain aspects, the operations 700 may further involve the circuit comparing the amplitude of the input signal to a threshold. In this case, the adjusting at block 706 may include using a first dead time if the amplitude is lower than the threshold and using a second dead time if the amplitude is higher than the threshold. The first dead time may be greater than the second dead time. For certain aspects, the operations 700 may further include the circuit adding dither to the input signal before the comparing. In some cases, the operations 700 may further entail the circuit modifying the threshold (e.g., during operation of the amplifier).

According to certain aspects, the parameter is a duty cycle of the drive signal or of a pulse-width modulated signal generated based on the input signal (e.g., in the PNS 204). For certain aspects, the operations 700 may further involve the circuit comparing the duty cycle to a threshold. In this case, the adjusting at block 706 may entail using a first dead time if the duty cycle is lower than the threshold and using a second dead time if the duty cycle is higher than the threshold. The first dead time may be greater than the second dead time. For certain aspects, the operations 700 may further include the circuit modifying the threshold (e.g., during operation of the amplifier).

According to certain aspects, the operations 700 may further involve the circuit detecting an envelope of the input signal and comparing an amplitude of the detected envelope to a threshold. In this case, the adjusting at block 706 may include the circuit using a first dead time if the amplitude of the detected envelope is lower than the threshold and using a second dead time if the amplitude of the detected envelope is higher than the threshold. For certain aspects, the circuit may detect the envelope by rectifying the input signal and low-pass filtering the rectified signal to generate the detected envelope.

Certain aspects of the present disclosure provide an amplifier. The amplifier generally includes circuitry configured to generate a drive signal based on an input signal; first and second transistors configured to generate an amplified signal; and first and second drivers coupled to the first and second transistors, respectively, and configured, based on the drive signal, to alternatively drive the first transistor and the second transistor with a time between deactivating the first transistor and activating the second transistor, wherein the time varies based at least in part on a parameter of the input signal or the drive signal.

According to certain aspects, the input signal comprises a digital signal (e.g., a digital audio signal).

According to certain aspects, the circuitry is further configured to adjust the time for the first and second drivers based on the parameter of the input signal or the drive signal and during generation of the amplified signal.

According to certain aspects, the parameter is an amplitude of the input signal. For certain aspects, the circuitry comprises a comparator configured to compare the amplitude of the input signal to a threshold, wherein the circuitry is further configured to adjust the time by using a first dead time if the amplitude is lower than the threshold and using a second dead time if the amplitude is higher than the threshold. The first dead time may be greater than the second dead time. For certain aspects, the circuitry is further configured to add dither to the input signal before the comparison. For other aspects, the amplifier further includes a combiner configured to add dither to the input signal before the comparison. For certain aspects, the circuitry is further configured to modify the threshold (e.g., during operation of the amplifier).

According to certain aspects, the amplifier further includes an envelope detector configured to detect an envelope of the input signal. In this case, the circuitry may include a comparator configured to compare an amplitude of the detected envelope to a threshold. Also, the circuitry may be further configured to adjust the time by using a first dead time if the amplitude of the detected envelope is lower than the threshold and using a second dead time if the amplitude of the detected envelope is higher than the threshold. For certain aspects, the envelope detector includes a rectifier configured to rectify the input signal and a low-pass filter configured to filter the rectified signal to generate the detected envelope. The rectifier and the low-pass filter may be digital or analog components.

According to certain aspects, the parameter is a duty cycle of the drive signal or of a pulse-width modulated signal generated based on the input signal. For certain aspects, the circuitry is further configured to compare the duty cycle to a threshold and to adjust the time by using a first dead time if the duty cycle is lower than the threshold and using a second dead time if the duty cycle is higher than the threshold. The first dead time may be greater than the second dead time. For certain aspects, the circuitry is further configured to modify the threshold (e.g., during operation of the amplifier). For certain aspects, the amplifier may further include a digital-domain noise shaper (e.g., PNS 204) configured to generate the pulse-width modulated signal based on the input signal.

According to certain aspects, the first transistor and the second transistor are both deactivated during the time.

According to certain aspects, the amplifier is a class-D amplifier. For certain aspects, the drive signal includes a pulse-width modulated signal based on the input signal.

According to certain aspects, the amplifier further includes a low-pass filter configured to filter the amplified signal. In this case, the amplified signal may be an amplified pulse-width modulated signal.

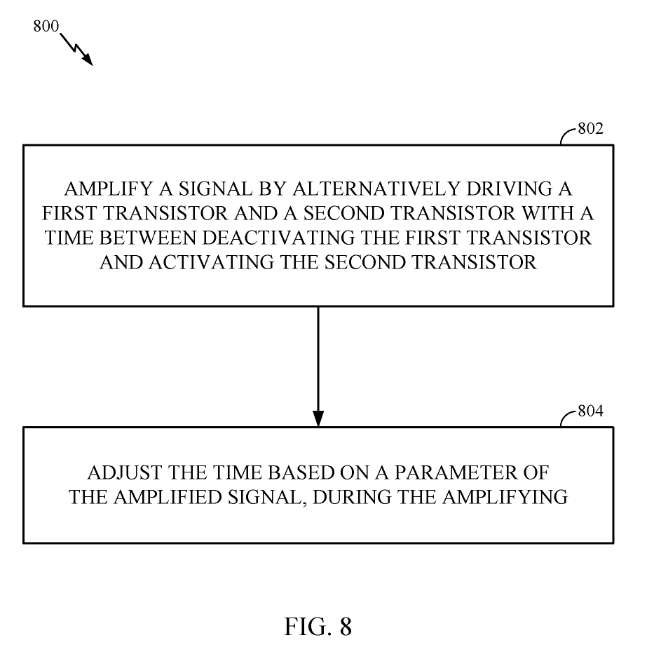

FIG. 8 is a flow diagram of example operations 800 for operating an amplifier, in accordance with certain aspects of the present disclosure. The operations 800 may be performed, for example, by a circuit, such as the class-D amplifier 100 of FIG. 1A, the class-D amplifier 150 of FIG. 1B, or the DDFA of FIG. 2.

The operations 800 may begin, at block 802, with the circuit amplifying a signal by alternatively driving a first transistor and a second transistor with a time between deactivating the first transistor and activating the second transistor. At block 804, the circuit may adjust the time based on a parameter of the amplified signal, during the amplifying. For example, the parameter may be the duty cycle or the amplitude of the amplified signal (e.g., after filtering or otherwise signal processing the amplified signal).

According to certain aspects, the amplifier is a class-D amplifier.

According to certain aspects, the operations 800 further entail the circuit low-pass filtering the amplified signal. For certain aspects, the amplified signal is an amplified pulse-width modulated signal.

According to certain aspects, the operations 800 further involve comparing the duty cycle of the amplified signal to a threshold. In this case, the adjusting at block 804 may include using a first dead time if the duty cycle is lower than the threshold and using a second dead time if the duty cycle is higher than the threshold. The first dead time may be greater than the second dead time. For certain aspects, the operations 800 further entail adding a jitter signal to the amplified signal to dither the duty cycle of the amplified signal before the comparing. The operations 800 may further include modifying the threshold (e.g., during operation of the amplifier, such as during the amplification of the signal at block 802).

According to certain aspects, the first transistor and the second transistor are both deactivated during the time.

Certain aspects of the present disclosure provide an amplifier. The amplifier generally includes first and second transistors configured to generate an amplified signal; and first and second drivers coupled to the first and second transistors, respectively, and configured to alternatively drive the first transistor and the second transistor with a time between deactivating the first transistor and activating the second transistor, wherein the time varies based at least in part on a parameter of the amplified signal. For certain aspects, the parameter is a duty cycle or an amplitude of the amplified signal.

According to certain aspects, the amplifier further includes circuitry (e.g., logic) configured to adjust the time for the first and second drivers based on the duty cycle of the amplified signal and during generation of the amplified signal. For certain aspects, the circuitry is further configured to compare the duty cycle of the amplified signal to a threshold, wherein the circuitry is configured to adjust the time by using a first dead time if the duty cycle is lower than the threshold and using a second dead time if the duty cycle is higher than the threshold. The first dead time may be greater than the second dead time. For certain aspects, the circuitry is further configured to add a jitter signal to the amplified signal to dither the amplified signal before the comparison. For other aspects, the amplifier further includes a combiner configured to add a jitter signal to the amplified signal to dither the amplified signal before the comparison. For certain aspects, the circuitry is further configured to modify the threshold.

According to certain aspects, the first transistor and the second transistor are both deactivated during the time.

According to certain aspects, the amplifier is a class-D amplifier.

According to certain aspects, the amplifier further includes a low-pass filter configured to filter the amplified signal. In this case, the amplified signal may include an amplified pulse-width modulated signal.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

For example, means for generating a drive signal may include a modulator (e.g., the PWM and error amplifier stage 102 illustrated in FIG. 1A or 1B or the pulse width modulator 202 depicted in FIG. 2). Means for switching may include a switching circuit, which may be implemented by one or more transistors (e.g., the transistors in the output stage 106 shown in FIG. 1A, 1B, or 2). Means for amplifying a signal may include an amplifier (e.g., the class-D amplifiers 100, 150 portrayed in FIGS. 1A and 1B or the DDFA 200 illustrated in FIG. 2), and more specifically, an output power stage (e.g., the output stage 106 depicted in FIG. 1A, 1B, or 2) and a driving circuit for driving the output power stage (e.g., drivers 104 shown in FIG. 1A or 1B). Means for adjusting a time may include circuitry (e.g., logic), including circuitry for determining a parameter of a signal (e.g., a digital-domain noise shaper, such as the PNS 204 illustrated in FIG. 2, or the PWM and error amplifier stage 102 depicted in FIG. 1A or 1B) and/or circuitry for adjusting control of the means for amplifying (e.g., the PWM and error amplifier stage 102 illustrated in FIG. 1A or 1B or the pulse width modulator 202 depicted in FIG. 2).

As used herein, the term “circuitry” may include any combination of analog circuitry, digital circuitry, and/or logic.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A method of operating an amplifier, comprising:
generating a drive signal based on an input signal;
amplifying the drive signal by alternatively driving a first transistor and a second transistor with a time between deactivating the first transistor and activating the second transistor; and
adjusting the time based on a parameter of the input signal or the drive signal, during the amplifying.

2. The method of claim 1, wherein the amplifier comprises a class-D amplifier and wherein generating the drive signal comprises generating a pulse-width modulated drive signal based on the input signal.

3. The method of claim 1, wherein the parameter comprises an amplitude of the input signal.

4. The method of claim 3, further comprising comparing the amplitude of the input signal to a threshold, wherein the adjusting comprises using a first dead time if the amplitude is lower than the threshold and using a second dead time if the amplitude is higher than the threshold.

5. The method of claim 4, wherein the first dead time is greater than the second dead time.

6. The method of claim 4, further comprising adding dither to the input signal before the comparing.

7. The method of claim 4, further comprising modifying the threshold during the amplifying.

8. The method of claim 1, wherein the input signal comprises a digital signal.

9. The method of claim 1, further comprising:
detecting an envelope of the input signal; and
comparing an amplitude of the detected envelope to a threshold, wherein the adjusting comprises using a first dead time if the amplitude of the detected envelope is lower than the threshold and using a second dead time if the amplitude of the detected envelope is higher than the threshold.

10. The method of claim 9, wherein detecting the envelope comprises rectifying the input signal and low-pass filtering the rectified input signal to generate the detected envelope.

11. The method of claim 1, wherein the parameter comprises a duty cycle of the drive signal or of a pulse-width modulated signal generated based on the input signal.

12. The method of claim 11, further comprising comparing the duty cycle to a threshold, wherein the adjusting comprises using a first dead time if the duty cycle is lower than the threshold and using a second dead time if the duty cycle is higher than the threshold.

13. The method of claim 12, wherein the first dead time is greater than the second dead time.

14. The method of claim 12, further comprising modifying the threshold during the amplifying.

15. An amplifier comprising:
circuitry configured to generate a drive signal based on an input signal;
first and second transistors configured to generate an amplified signal; and
first and second drivers coupled to the first and second transistors, respectively, and configured, based on the drive signal, to alternatively drive the first transistor and the second transistor with a time between deactivating the first transistor and activating the second transistor, wherein the time varies based at least in part on a parameter of the input signal or the drive signal.

16. The amplifier of claim 15, wherein the circuitry is further configured to adjust the time based on the parameter of the input signal or the drive signal and during generation of the amplified signal.

17. The amplifier of claim 15, wherein the parameter comprises an amplitude of the input signal.

18. The amplifier of claim 17, wherein the circuitry comprises a comparator configured to compare the amplitude of the input signal to a threshold, wherein the circuitry is further configured to adjust the time by using a first dead time if the amplitude is lower than the threshold and using a second dead time if the amplitude is higher than the threshold.

19. The amplifier of claim 18, wherein the first dead time is greater than the second dead time.

20. The amplifier of claim 18, further comprising a combiner configured to apply dither to the input signal before the comparison.

21. The amplifier of claim 18, wherein the circuitry is further configured to modify the threshold.

22. The amplifier of claim 15, further comprising an envelope detector configured to detect an envelope of the input signal, wherein:
the circuitry comprises a comparator configured to compare an amplitude of the detected envelope to a threshold; and
the circuitry is further configured to adjust the time by using a first dead time if the amplitude of the detected envelope is lower than the threshold and using a second dead time if the amplitude of the detected envelope is higher than the threshold.

23. The amplifier of claim 22, wherein the envelope detector comprises:
a rectifier configured to rectify the input signal; and
a low-pass filter configured to filter the rectified input signal to generate the detected envelope.

24. The amplifier of claim 15, wherein the input signal comprises a digital signal.

25. The amplifier of claim 15, wherein the parameter comprises a duty cycle of the drive signal or of a pulse-width modulated signal generated based on the input signal.

26. The amplifier of claim 25, wherein the circuitry is further configured to compare the duty cycle to a threshold and to adjust the time by using a first dead time if the duty cycle is lower than the threshold and using a second dead time if the duty cycle is higher than the threshold.

27. The amplifier of claim 26, wherein the circuitry is further configured to modify the threshold.

28. The amplifier of claim 25, further comprising a digital-domain noise shaper configured to generate the pulse-width modulated signal based on the input signal.

29. The amplifier of claim 15, wherein the amplifier comprises a class-D amplifier and wherein the drive signal comprises a pulse-width modulated signal based on the input signal.

30. An apparatus for amplifying an input signal, comprising:
means for generating a drive signal based on the input signal;
means for amplifying the drive signal by alternatively driving first and second means for switching with a time between deactivating the first means for switching and activating the second means for switching; and
means for adjusting the time based on a parameter of the input signal or the drive signal, during the amplifying.
